(19) United States
(12) Patent Application Publication
(10) Pub. No.: US 2012/0241816 A1
(43) Pub. Date: Sep. 27, 2012

(54) Stabilization of Metal Silicides in PFET Transistors by Incorporation of Stabilizing Species in a Si/Ge Semiconductor Material

(75) Inventors: Stefan Flachowsky, Dresden (DE); Thilo Scheiper, Dresden (DE); Peter Javorka, Radeburg (DE)

(73) Assignees: GLOBALFOUNDRIES Dresden Module One Limited Liability Company & Co., KG, Dresden (DE); GLOBALFOUNDRIES INC., Grand Cayman (KY)

(21) Appl. No.: 13/052,772

(22) Filed: Mar. 21, 2011

(51) Int. Cl. H01L 29/772; H01L 21/336

(52) U.S. Cl. 257/192; 438/285; 257/E21.409; 257/E29.242

(57) ABSTRACT

When forming sophisticated P-channel transistors, the metal silicide agglomeration in a germanium-containing strain-inducing semiconductor alloy may be avoided or at least significantly reduced by incorporating a carbon and/or nitrogen species in a highly controllable manner. In some illustrative embodiments, the carbon species or nitrogen species is incorporated during the epitaxial growth process so as to form a surface layer of the strain-inducing semiconductor alloy with a desired nitrogen and/or carbon concentration and with a desired thickness without unduly affecting any other device areas.

### BACKGROUND OF THE INVENTION

1. Field of the Invention

Generally, the present disclosure relates to integrated circuits, and, more particularly, to transistors comprising an epitaxially grown silicon and germanium containing mixture in the active regions of the transistors.

2. Description of the Related Art

The fabrication of complex integrated circuits requires the provision of a large number of transistor elements, which represent the dominant circuit elements in complex integrated circuits. For example, several hundred millions of transistors may be provided in presently available complex integrated circuits, wherein performance of the transistors in the speed critical signal paths substantially determines overall performance of the integrated circuit. Generally, a plurality of process technologies are currently practiced, wherein, for complex circuitry, such as microprocessors, storage chips and the like, CMOS technology is currently the most promising approach due to the superior characteristics in view of operating speed and/or power consumption and/or cost efficiency. In CMOS circuits, complementary transistors, i.e., P-channel transistors and N-channel transistors, are used for forming circuit elements, such as inverters and other logic gates to design highly complex circuit assemblies, such as CPUs, storage chips and the like. During the fabrication of complex integrated circuits using CMOS technology, millions of transistors, i.e., N-channel transistors and P-channel transistors, are formed on a substrate including a crystalline semiconductor layer. A MOS transistor, or generally a field effect transistor, irrespective of whether an N-channel transistor or a P-channel transistor is considered, comprises so-called PN junctions that are formed by an interface positioned between highly doped drain and source regions and an inversely or weakly doped channel region disposed between the drain region and the source region. The conductivity of the channel region, i.e., the drive current capability of the conductive channel, is controlled by a gate electrode formed in the vicinity of the channel region and separated therefrom by a thin insulating layer. The conductivity of the channel region, upon formation of a conductive channel due to the application of an appropriate control voltage to the gate electrode, depends on, among other things, the mobility of the charge carriers and, for a given extension of the channel region in the transistor width direction, on the distance between the source and drain regions, which is also referred to as channel length. Thus, the reduction of the channel length, and associated therewith the reduction of the channel resistivity, is a dominant design criterion for accomplishing an increase in the operating speed of the integrated circuits.

Upon continuously reducing the channel length of field effect transistors, generally an increased degree of capacitive coupling is required in order to maintain controllability of the channel region, which may typically require an adaptation of a thickness and/or material composition of the gate dielectric material. For example, for a gate length of approximately 80 nm, a gate dielectric material based on silicon dioxide with a thickness of less than 2 nm may be required in high speed transistor elements, which may, however, result in increased leakage currents caused by hot carrier injection and direct tunneling of charge carriers through the extremely thin gate dielectric material. Since a further reduction in thickness of silicon dioxide-based gate dielectric materials may increasingly become incompatible with thermal power requirements of sophisticated integrated circuits, other alternatives have been developed in increasing the charge carrier mobility in the channel region, thereby also enhancing overall performance of field effect transistors.

One promising approach in this respect is the generation of a certain type of strain in the channel region, since the charge carrier mobility in silicon strongly depends on the strain conditions of the crystalline material. For example, for a standard crystallographic configuration of the silicon-based channel region, a compressive strain component in a P-channel transistor may result in a superior mobility of holes, thereby increasing switching speed and drive current of P-channel transistors. The desired compressive strain component may be obtained according to well-established approaches by incorporating a strain-inducing semiconductor material, for instance in the form of a silicon/germanium mixture or alloy, in the active region of the P-channel transistor. For example, after forming the gate electrode structure, corresponding cavities may be formed laterally adjacent to the gate electrode structure in the active region and may be refilled with the silicon/germanium alloy which, when grown on the silicon material, may have an internal strained state, which in turn may induce a corresponding compressive strain component in the adjacent channel region. Consequently, a plurality of process strategies has been developed in the past in order to incorporate a highly strained silicon/germanium material in the drain and source areas of P-channel transistors.

The incorporation of a silicon/germanium alloy into the active regions of P-channel transistors is a very promising approach for significantly improving device performance of these transistors, wherein the efficiency of this performance enhancing mechanism strongly depends on the material characteristics of the silicon/germanium alloy and its lateral offset from the channel region of the transistor. Since it is very difficult to achieve high germanium concentration in order to provide a more pronounced difference in the natural lattice constant between the silicon/germanium material and the silicon base material, it is very important to reduce the lateral offset of the strained silicon/germanium material and also to incorporate a desired large amount of this material. Consequently, a plurality of process techniques have been developed in which appropriately shaped cavities are formed and subsequently refilled and even over-filled with the strain-inducing silicon/germanium material, while at the same time attempting to provide a high germanium concentration of, for example, 25-35 atomic percent. To this end, typically, selective epitaxial growth techniques are applied in which process parameters such as temperature, pressure and gas flow rates are specifically designed so as to initiate a pronounced material deposition on exposed crystalline surface areas, even with a certain degree of selectivity with respect to selected crystal planes, while on the other hand a pronounced material deposition on dielectric surface areas, such as silicon dioxide, silicon nitride and the like, is significantly suppressed. In this manner, a desired amount of the strain-inducing silicon/germanium material may be grown in the cavities, which in turn substantially determines the lateral offset from the channel region.

On the basis of the strain-inducing semiconductor material, superior transistor performance may be obtained, for instance in particular for P-channel transistors, thereby reducing the imbalance with respect to charge carrier mobility between N-channel transistors and P-channel transistors. In addition, in sophisticated applications, further techniques and mechanisms may frequently be implemented in order to enhance overall transistor performance. For example, sophisticated gate architectures are increasingly used in which high-k dielectric materials may be provided in the gate insulation layers in combination with appropriate work function metals and electrode materials in order to enhance channel controllability while not unduly increasing the static and dynamic leakage currents. In this respect, it should be appreciated that a high-k dielectric material is to be understood as a dielectric material having a dielectric constant of 10.0 and higher. In some approaches, a corresponding complex high-k metal gate electrode structure may be provided in an early manufacturing stage, thereby requiring a plurality of complex process steps for encapsulating the sensitive gate materials, while, in other approaches, a more or less conventional gate electrode structure is initially provided, while certain materials thereof, such as a polysilicon material, are replaced in a very advanced manufacturing stage, thereby incorporating a highly conductive electrode material, possibly in combination with a high-k gate dielectric material.

Consequently, based on these process strategies, high performance transistors may be provided with a high packing density due to the reduced critical dimensions, which may be 50 nm and less in sophisticated semiconductor devices. It turns out, however, that significant yield loss may be observed in a process phase after which the basic transistor configuration has been completed, as will be described in more detail with reference to FIGS. 1a-1b.

FIG. 1a schematically illustrates a cross-sectional view of a semiconductor device 100 in an advanced manufacturing stage. As shown, the device 100 comprises a substrate 101, such as a semiconductor material and the like, above which is formed a semiconductor layer 102, which in turn is laterally divided into a plurality of active regions, which are to be understood as semiconductor regions, in and above which one or more transistors are to be formed. For convenience, a single active region 102A is illustrated, which is laterally delineated by an isolation region 102B, such as a shallow trench isolation. Depending on the overall device requirements, the substrate 101 and the semiconductor layer 102, for instance initially provided as a silicon material, may form a silicon-on-insulator (SOI) architecture when a buried insulating material (not shown) is formed directly below the semiconductor layer 102. In other cases, initially the semiconductor layer 102 represents a part of the crystalline material of the substrate 101 when a bulk configuration is to be used for the device 100. Furthermore, a transistor 150 is formed in and above the active region 102A and represents a P-channel transistor, which requires enhanced performance characteristics which are obtained in part by incorporating a strain-inducing silicon/germanium alloy 152 into the active region 102A, as discussed above. Furthermore, appropriate drain and source regions 151 are formed in the active region 102A, which have any appropriate lateral and vertical profile so as to comply with the requirements of the transistor 150. Moreover, the transistor 150 comprises a gate electrode structure 160 having any appropriate geometric configuration, for instance in terms of length and width, wherein, for sophisticated applications, a gate length, i.e., in FIG. 1a, the horizontal extension of an electrode material 162 of the gate electrode structure 160, may be 50 nm and less. As indicated above, in sophisticated applications, the gate electrode structure 160 comprises a gate insulation layer 161 including a high-k dielectric material so as to provide superior channel controllability while not unduly increasing the overall leakage currents. Furthermore, a further electrode material 162A, for instance in the form of tantalum nitride and the like, possibly in combination with a work function metal species, such as aluminum and the like, is typically formed above the gate dielectric material 161, thereby adjusting an appropriate work function and thus threshold voltage of the transistor 150. Furthermore, an appropriate spacer structure 163 is typically provided and comprises one or more spacer elements, possibly in combination with etch stop liners and the like. For example, the structure 163 may comprise appropriate protective liner materials for laterally encapsulating sensitive gate materials, such as the gate dielectric material 161 and in particular the electrode material 162A. Furthermore, a metal-containing portion 162B, typically provided in the form of a metal silicide, is frequently formed in and above the electrode material 162 in order to further enhance overall conductivity of the gate electrode structure 160, in particular with respect to contact resistivity and the like. Similarly, a metal silicide 153 is formed in the drain and source regions 151 and, due to the incorporation of the silicon/germanium material 152, the metal silicide 153 is thus formed within the silicon/germanium material 152.

The semiconductor device 100 as shown in FIG. 1a may be formed on the basis of sophisticated process techniques in which the active region 102A may be provided by forming the isolation region 102B and incorporating a desired well dopant species so as to determine the basic transistor characteristics. In some cases, the active region 102A may receive an additional semiconductor alloy 102C in order to appropriately adjust the electronic characteristics of a channel region 155 of the transistor 150 with respect to the gate electrode structure 160. For example, a certain band gap offset between N-channel transistors and P-channel transistors may be necessary in order to obtain the desired low threshold voltage for certain transistors, which may frequently be accomplished by incorporating the channel material 102C in one type of transistor, such as the P-channel transistor 150. To this end, a silicon/germanium material with a specific thickness and material composition is formed on the active region 102A, so as to form a part thereof during the further processing. To this end, well-established epitaxial growth techniques are typically applied. Thereafter, the gate electrode structure 160 may be formed on the basis of complex deposition, lithography and etch techniques in order to provide appropriate materials for the gate dielectric layer 161, the electrode layer 162A and the electrode material 162. Additional hard mask materials, such as silicon nitride and the like, are typically provided and may be used during the further processing in order to reliably encapsulate the sensitive materials 161, 162A, 162 in combination with an appropriate spacer or liner of the structure 163. Thereafter, cavities may be formed in the active region 102A, while other active regions, such as the active regions of N-channel transistors, may be masked in order to avoid a deposition of a silicon/germanium material therein. As discussed above, by appropriately shaping and dimensioning the cavities, the lateral offset and basically the amount of silicon/germanium material may be controlled during a subsequent selective epitaxial growth process for forming the material 152. As discussed above, typically, process parameters are selected so as to achieve a bottom-to-top fill behavior during the epitaxial growth of the silicon/germanium material 152. Thereafter, the processing is continued by incorporating drain and source dopant species, possibly in combination with a counter-doping species on the basis of implantation processes and masking regimes, while also the spacer structure 163 may be completed and the final dopant profile may be established by incorporating further drain and source dopant species and performing any anneal processes. It should be appreciated that, at any appropriate manufacturing stage, any cap material of the gate electrode structure 160 may be removed and the device 100 is prepared for forming the metal silicide materials 153 and 162B. To this end, well-established silicidation techniques may be applied in order to form metal silicide on any exposed semiconductor surface areas. It turns out, however, that, upon forming the metal silicide 153, a pronounced non-continuous material layer is formed in the silicon/germanium material 152, thereby creating a “spotty” metal silicide region. For example, more or less pronounced “holes” 153A are present within the material 153, which may have a significant influence on the further processing of the device 100.

FIG. 1b schematically illustrates the device 100 in a further advanced manufacturing stage in which a contact level 120 is provided and comprises one or more dielectric materials, such as an etch stop layer 121 and an interlayer dielectric material 122, in which are formed contact elements 123, which may connect to the drain and source regions 151 and to the gate electrode structure 160 (not shown) in accordance with the overall device requirements. Since the metal silicide 153 is specifically provided so as to reduce the contact resistance of the transistor 150, the presence of a “spotty” silicide layer may generally reduce the overall conductivity. A further very important aspect of the holes 153A that are present in the metal silicide material 153 is related to the manufacturing process for forming the contact elements 123, since the etch stop capabilities of the metal silicide material 153 are severely deteriorated, thereby inducing a high risk of deeply etching into the active region 102A, as indicated by 123A. That is, after the deposition of the dielectric materials 121, 122, sophisticated patterning processes are applied in which it is etched through the material 122, wherein the corresponding etch process may be controlled on the basis of the layer 121, which is subsequently opened by a further etch step, which is typically highly selective with respect to the metal silicide material 153. Due to the presence of the holes 153A, the corresponding etch chemistry etches deeply into the active region 102A, thereby forming the channels 123A, which may be filled with a conductive material, such as tungsten and the like, thereby significantly altering the characteristics of the transistor 150, which may even result in a complete shorting of PN junctions and shortings of adjacent contact elements 123 via the well region of different transistors.

It has been recognized that the presence of the holes 153A is strongly correlated with the high germanium concentration within the material 153. Without intending to restrict the present application to the following explanation, it is believed that, in particular, any further thermal treatments after incorporating the metal silicide 153 may result in a certain nickel diffusion and thus nickel agglomeration, thereby increasingly forming the holes 153A. Any such processes performed on the basis of elevated temperatures may be the formation of the material 121, which is frequently provided in the form of a highly stressed dielectric material, which may require additional heat treatments, radiation treatments in order to further enhance the internal dielectric stress level. On the other hand, avoiding any such processes with elevated temperatures after incorporating the metal silicide 153 may result in inferior device characteristics and may also significantly restrict the overall flexibility in designing the manufacturing flow for fabricating complex semiconductor devices. Similarly, reducing the germanium concentration is also less than desirable, even if a corresponding reduction in germanium concentration would be restricted to an upper portion of the material 153 since, in particular in highly scaled devices, nevertheless, a pronounced reduction of the overall strain in the channel region 155 can be observed, thereby also reducing overall performance of the transistor 150.

For this reason, it has been proposed to incorporate a carbon species or a nitrogen species into the material 153 since it is known that these atomic species implanted prior to or after the silicide formation may reduce the “spotty” nature of the metal silicide 153. The implanted nitrogen and/or carbon atoms stabilize the silicide and avoid agglomeration at higher temperatures. The implantation of a carbon or nitrogen species, however, may cause significant alteration of device characteristics, for instance in highly sensitive devices, such as diode structures, which are typically implemented in complex semiconductor devices for various purposes, in particular for monitoring the temperature in critical device areas. For example, substrate diodes and film diodes are typically provided in sophisticated SOI devices, wherein the efficiency of the overall temperature monitoring strongly depends on the diode characteristics, which, however, turn out to be significantly affected by the implanted nitrogen and/or carbon species. For example, a very pronounced deterioration of diode ideology has been observed upon incorporating a carbon or nitrogen species on the basis of implantation processes even when using moderately low implantation energies. For this reason, it has been proposed to appropriately mask any such sensitive device areas in order to substantially restrict the implantation process to P-channel transistors. In this case, however, other device areas, such as isolation regions, such as the region 102B, in the vicinity of P-channel transistors may be exposed to the implantation process, thereby significantly modifying the characteristics of the dielectric materials provided therein. For example, it is known that silicon dioxide, when “doped” with carbon or nitrogen, exhibits a significantly higher etch rate compared to non-doped silicon dioxide, which may result in a very pronounced surface topography during the further processing after the corresponding implantation process, that is, any additional critical process steps, such as a possible encapsulation of sensitive gate materials, lithography processes and the like, sensitively depend on the surface topography and may thus cause significant device modifications.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which a nitrogen species and/or a carbon species may be efficiently incorporated into a strain-inducing semiconductor alloy in a locally restricted manner without significantly affecting other device areas, such as diode structures, isolation regions and the like. To this end, in some illustrative embodiments, the nitrogen species and/or the carbon species may be incorporated into the strain-inducing semiconductor alloy upon forming the same on the basis of appropriate process techniques, thereby avoiding the presence of any such species in any other device areas. For example, epitaxial growth techniques may be readily adapted so as to incorporate nitrogen and/or carbon at any appropriate phase during the deposition process, for instance during a final phase, in order to provide a certain thickness of the strain-inducing semiconductor alloy that complies with further processing, when forming a metal/semiconductor compound therein in a later manufacturing stage. On the other hand, due to the highly controlled incorporation of the carbon and/or nitrogen species, any undue effect of these atoms may be avoided due to the precise positioning within the strain-inducing alloy, while not even unduly affecting other areas of the active region.

In other illustrative embodiments disclosed herein, the nitrogen and/or carbon species may be incorporated by implantation techniques in an advanced manufacturing stage, however, without inducing an inhomogeneous effect in other device areas, such as isolation regions. To this end, the species may be incorporated through contact openings, while other contact openings may be masked by providing an appropriate sacrificial fill material.

One illustrative method disclosed herein comprises performing an epitaxial growth process so as to form, in a first phase of the epitaxial growth process, a crystalline silicon/germanium-containing material on a semiconductor material of an active region of a P-channel transistor and so as to form, in a subsequent second phase of the epitaxial growth process, at least one of a carbon-doped and a nitrogen-doped silicon/germanium-containing material. The method further comprises forming drain and source regions in the active regions and forming a metal/semiconductor compound in the carbon-doped and/or nitrogen-doped silicon/germanium-containing material.

A further illustrative method disclosed herein relates to forming a semiconductor device. The method comprises forming cavities in an active region of a P-channel transistor laterally adjacent to a gate electrode structure of the transistor. The method further comprises forming a strain-inducing semiconductor alloy in the cavities. Moreover, a carbon species and/or a nitrogen species is provided in the strain-inducing semiconductor alloy so as to have a highest concentration at and near a surface thereof and so as to have a lowest concentration at an interface formed between the strain-inducing semiconductor alloy and a remaining portion of the active region. Moreover, the method comprises forming drain and source regions at least in the strain-inducing semiconductor alloy. Additionally, a metal silicide is formed in the strain-inducing semiconductor alloy.

One illustrative semiconductor device disclosed herein comprises an active region formed above a substrate and a gate electrode structure formed on the active region. Furthermore, the semiconductor device comprises drain and source regions formed in the active region. Moreover, a strain-inducing germanium-containing semiconductor material is formed at least partially in the drain and source regions. Moreover, the device comprises a metal/semiconductor compound formed in the germanium-containing semiconductor material and comprising carbon and/or nitrogen with a concentration that is greater than a concentration of carbon and/or nitrogen in a remaining portion of the active region.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a semiconductor device comprising a P-channel transistor formed on the basis of sophisticated conventional process techniques, wherein a “spotty” metal silicide may result in inferior performance;

FIGS. 2a-2e schematically illustrate cross-sectional views of a semiconductor device during various manufacturing stages when incorporating a strain-inducing semiconductor alloy on the basis of a nitrogen and/or carbon species formed in an upper portion thereof, according to illustrative embodiments; and

FIG. 2f schematically illustrates the device in a further advanced manufacturing stage in which at least a portion of a contact level may be provided, wherein, in some illustrative embodiments, a metal silicide may be formed through contact openings, possibly in combination with an appropriately masked implantation process for incorporating a carbon and/or nitrogen species.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally provides semiconductor devices and manufacturing techniques in which a nitrogen and/or carbon species may be efficiently incorporated into a strain-inducing semiconductor alloy, such as a silicon/germanium alloy and the like, while at the same time not unduly affecting other device areas, such as sensitive diode structures and the like. To this end, in some illustrative embodiments, the nitrogen and/or carbon species may be incorporated into the selectively grown strain-inducing semiconductor alloy in a highly controllable manner during the epitaxial growth process, thereby incorporating the nitrogen and/or carbon species without affecting any other device areas. In some illustrative embodiments, the nitrogen and/or carbon species may be incorporated during a final phase of the deposition process, thereby even providing these atomic species in a highly locally restricted manner within the strain-inducing semiconductor alloy, thereby reducing any possible effects of these atomic species on the overall characteristics of the transistors. In this manner, a desired high germanium concentration may be established within the entire strain-inducing semiconductor alloy, without requiring specifically adapted vertical concentration profiles of the germanium species or avoiding the incorporation of specific “cap layers” with a significantly reduced germanium concentration, which in turn may result in a reduced overall strain-inducing effect. For example, due to the highly controllable deposition process, the carbon and/or nitrogen species may be incorporated at a certain depth up to the surface of the strain-inducing semiconductor alloy with highly controllable thickness, for instance in the range of 25 nm and less, depending on the process parameters used for forming the corresponding metal/semiconductor compound, such as a nickel-containing metal silicide. Consequently, by the incorporation of the carbon and/or nitrogen species, a high degree of flexibility is achieved for the further processing of the device, for instance with respect to performing additional processes with elevated temperatures, for instance as required for providing a highly stressed interlayer dielectric material and the like. For example, metal silicide may also be provided in a late manufacturing stage, i.e., after forming at least a portion of an interlayer dielectric material, for instance by forming contact openings through which the metal silicide may be formed, wherein the presence of the nitrogen and/or carbon species may also result in superior diffusion conditions during the further processing. For example, when applying sophisticated replacement gate approaches, in which contact elements may be formed prior to actually forming the replacement gate structure, which in turn may also require the application of fusion processes and the like.

In other illustrative embodiments, the nitrogen and/or carbon species may be incorporated prior to or after forming a metal silicide through contact openings, wherein other contact openings, for instance connecting to diode structures and the like, may be efficiently filled with a sacrificial fill material, thereby avoiding undue interaction during a corresponding implantation process. Moreover, the interaction of the implantation process with other device areas, such as isolation regions, may be highly uniform for the entire exposed surface areas, thereby also not unduly contributing to a pronounced surface topography during the further processing.

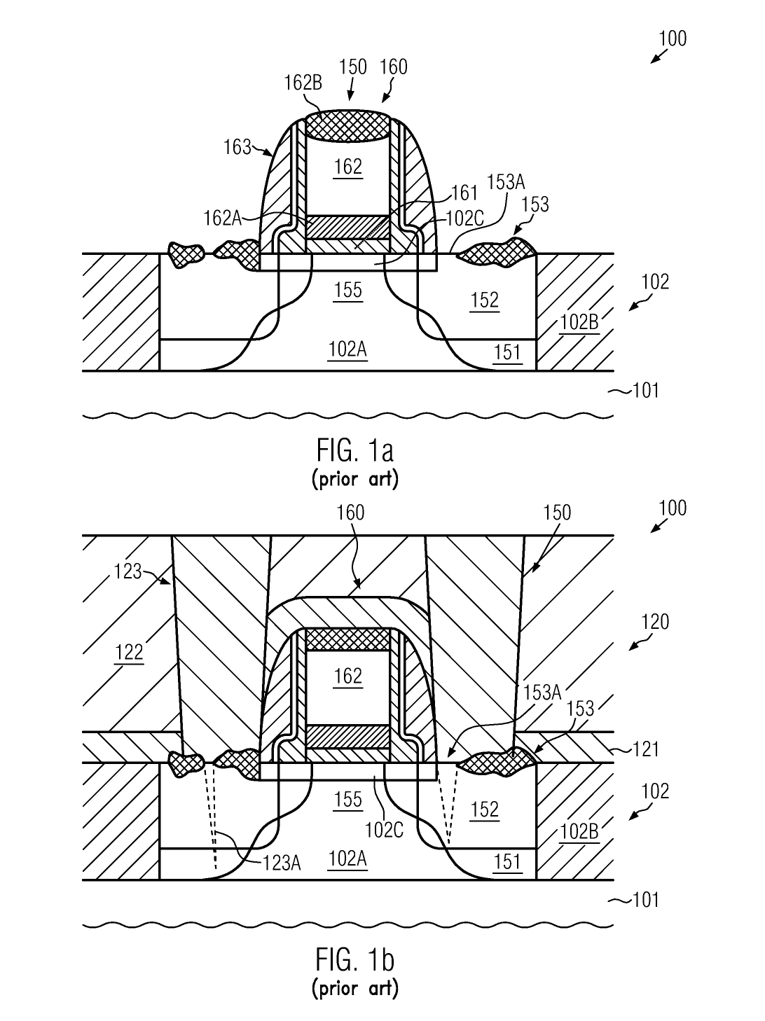

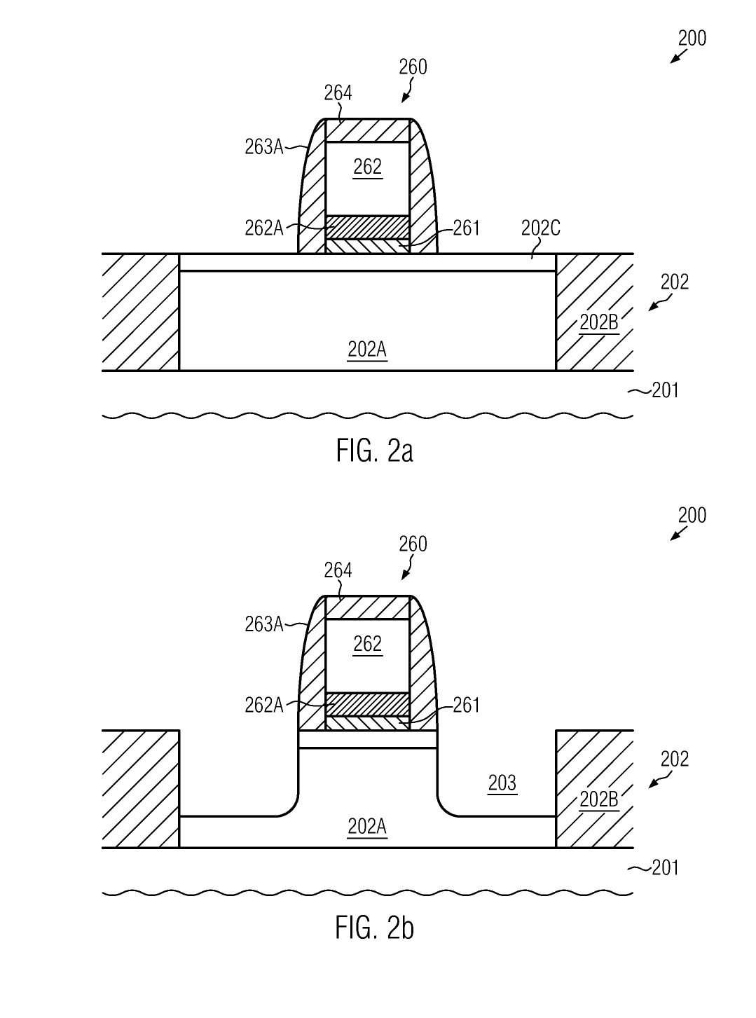

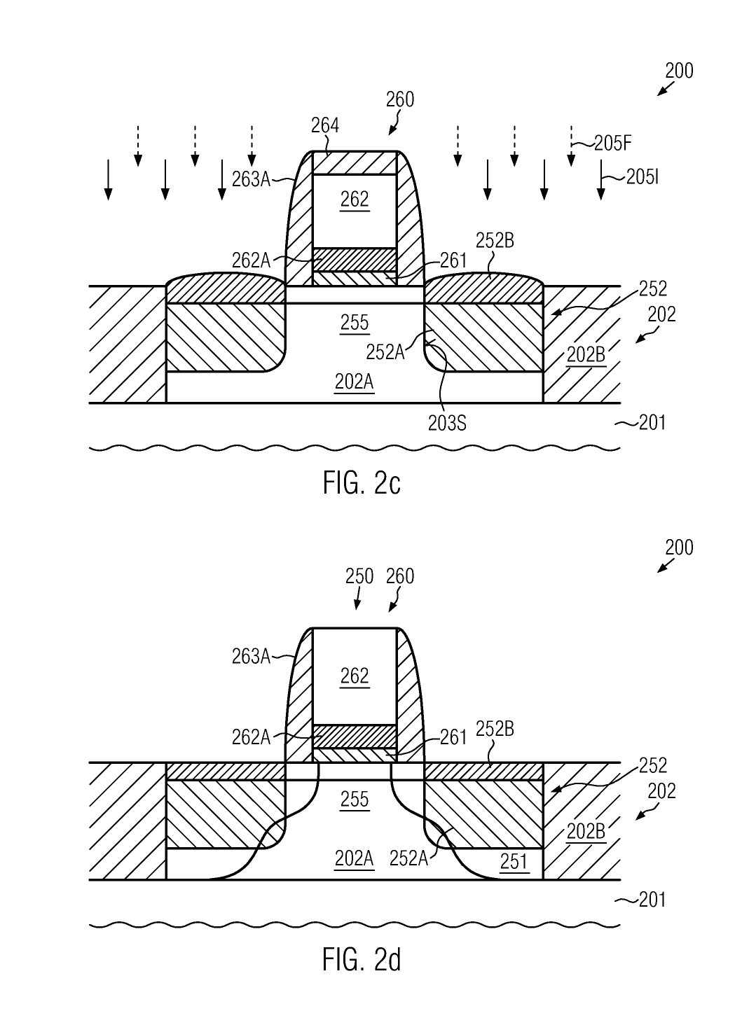

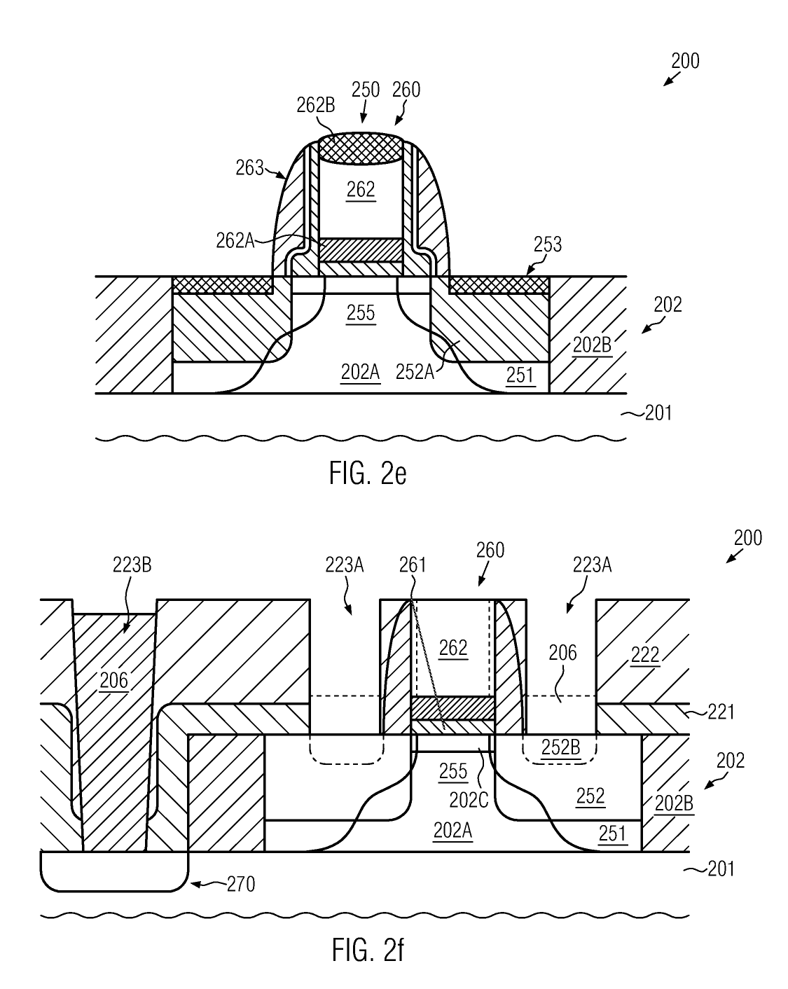

With reference to FIGS. 2a-2f, further illustrative embodiments will now be described in more detail, wherein reference may also be made to FIGS. 1a-1b, if required.

FIG. 2a schematically illustrates a cross-sectional view of a semiconductor device 200 comprising a substrate 201 and a semiconductor layer 202 formed thereabove. As indicated with reference to the device 100, the substrate 201, which may represent any appropriate carrier material, and the semiconductor layer 202 may form an SOI configuration or a bulk configuration, depending on the overall process and device requirements. Furthermore, a plurality of active regions are laterally delineated by an isolation region 202B, wherein, for convenience, a single active region 202A is illustrated in FIG. 2a. In the embodiment shown, the active region 202A may correspond to the active region of a P-channel transistor to be formed in and above the active region 202A. In some illustrative embodiments, as shown in FIG. 2a, an additional semiconductor material 202C may be formed in the active region 202A in order to adjust appropriate electronic characteristics, for instance with respect to the threshold voltage of a transistor still to be formed. For example, the material 202C, which may also be indicated as a threshold voltage adjusting semiconductor alloy, may be provided with an appropriate thickness of, for example, 5-50 nm and with an appropriate material composition, for instance, in the form of a silicon/germanium alloy having a germanium concentration of 10-30 atomic percent. It should be appreciated, however, that, in other illustrative embodiments, a corresponding adaptation of the electronic characteristics by means of the layer 202C may not be required. Furthermore, in the manufacturing stage shown, a gate electrode structure 260 may be formed on the active region 202A and may have any appropriate configuration as required for the further processing. For example, as indicated above, in some cases, the gate electrode structure 260 may have a gate dielectric layer 261, which may comprise a high-k dielectric material, while, in other cases, a conventional dielectric material, such as silicon oxynitride and the like, may be provided. As also indicated above, a high-k dielectric material may be provided in a very advanced manufacturing stage in other approaches, which are typically referred to as replacement gate approaches. Similarly, an electrode material 262, for instance in the form of a semiconductor material, such as amorphous and/or polycrystalline silicon, may be provided, possibly in combination with an additional metal-containing electrode material 262A, for instance in the form of tantalum nitride and the like. Moreover, a dielectric cap layer or layer system 264 may be formed above the electrode material 262, for instance comprised of a silicon nitride material, silicon dioxide and the like. Similarly, a spacer or spacer structure 263A may be provided so as to laterally confine any sensitive materials, such as the materials 261 and 262A, if provided in the form of a high-k dielectric material and a metal-containing electrode material.

The semiconductor device 200 as shown in FIG. 2a may be formed on the basis of any appropriate manufacturing strategy, for instance on the basis of process techniques as previously described.

FIG. 2b schematically illustrates the device 200 in a further advanced manufacturing stage in which cavities 203 may be provided in the active region 202A and may have any appropriate size and shape so as to comply with the desired transistor characteristics. To this end, any etch strategies may be applied, for instance plasma assisted etch recipes, wet chemical etch recipes or a combination thereof, wherein the size and shape of the cavities 203 may be efficiently adjusted by selecting appropriate etch chemistries and/or process parameters. It should be appreciated that, upon performing any such etch sequence, other device areas, such as the active regions of N-channel transistors, diode structures and the like, may be appropriately covered by a mask layer, such as a resist material, possibly in combination with a silicon nitride material, a silicon dioxide material and the like.

FIG. 2c schematically illustrates the device 200 according to illustrative embodiments in which an epitaxial growth process 205 may be applied so as to form a strain-inducing semiconductor alloy 252, which may comprise a desired amount of germanium so as to induce a desired magnitude and type of strain in a channel region 255. In some illustrative embodiments, the growth process 205 may be performed so as to form a first portion 252A of the material 252 during a first phase 205I of the process 205, in which process parameters and in particular precursor gases of the deposition atmosphere are appropriately selected so as to obtain the material 252A having the desired composition, wherein, if necessary, a drain and source dopant species may also be incorporated. Since the deposition process 205I is a highly controllable process, the characteristics of the material 252A may be efficiently adjusted, while also the amount thereof may be controlled by the process parameters, for instance by selecting a desired deposition time. Moreover, as already described above, in many cases, the selectivity of the deposition process 205 may even be adjusted so as to relate to different crystal planes of the base material 202A, thereby achieving a desired bottom-to-top fill behavior. For example, the material deposited during the process 205I may preferably adhere to (100) surface planes, while an adherence to (110) planes may be less pronounced. In other cases, the cavities 203 (FIG. 2b) may be provided in a well-defined “sigma shaped” configuration in which sidewalls may be inclined and may represent specific crystal planes, which may also have reduced deposition efficiency, thereby also enabling a superior bottom-to-top fill behavior.

The process 205 may further comprise a second deposition phase 205F, which may also be referred to as a final phase, in which a material portion 252B may be formed so as to contain a desired concentration of nitrogen and/or carbon. For example, in some illustrative embodiments, a carbon species may be incorporated, which may result in a very efficient blocking of nickel agglomeration when forming a nickel-based metal silicide in a later manufacturing stage. To this end, appropriate carbon-containing precursor gases may be added to the deposition ambient of the process phase 205F, for which well-established recipes and process tools may be used. In this manner, the carbon and/or nitrogen species may be incorporated into the material 252B in a well-controlled locally restricted manner while also providing a substantially uniform concentration profile within the material portion 252B. For example, a maximum concentration, which may be substantially constant except for any process-related fluctuations, may be one atomic percent or less, while, in other cases, even an increased concentration may be incorporated if considered appropriate for obtaining the desired agglomeration-hindering effect. In some illustrative embodiments, the portion 252B may be formed with an appropriate depth or thickness that is appropriately adapted to a desired depth or thickness of a metal/semiconductor compound to be formed in the material 252 in a later manufacturing stage. For example, in some illustrative embodiments, a thickness of the portion 252B may be 5-25 nm. It should be appreciated that the spatial dimensions of the region 252B are to be understood as being defined by an interface formed with any neighboring material that differs in material composition and/or wherein a concentration of carbon and/or nitrogen drops by at least two orders of magnitude compared to a maximum carbon and/or nitrogen concentration. That is, the regions 252B, 252A may differ in their concentrations with respect to carbon and/or nitrogen, wherein a “boundary” may be considered as an area in which the concentration of nitrogen and/or carbon is less than by at least two orders of magnitude compared to a position or area of the region 252 having a maximum value of the corresponding nitrogen and/or carbon concentration. For example, due to the well-defined deposition conditions during the process 205, the portion 252B may form a surface layer having a well-defined thickness in the above-specified range, wherein any transition area with the significant drop of the carbon and/or nitrogen concentration may have a thickness of several nanometers and significantly less.

In other illustrative embodiments (not shown), the portion 252B may be laterally restricted, for instance, the length, i.e., in FIG. 2c, the horizontal extension of the regions 252A, 252B, may be different, for instance, when a pronounced lateral growth on substantially vertical sidewalls 203S may occur upon forming the portion 252A in the initial phase 205I. In this case, the portion 252B may be “laterally” offset from the gate electrode structure by a corresponding portion of the material 252A. Thereafter, the further processing may be continued on the basis of any appropriate process strategy.

FIG. 2d schematically illustrates the device 200 wherein a transistor 250 may have its basic configuration. That is, drain and source regions 251 may be formed in the active region 202A and thus at least partially within the strain-inducing material 252 comprising the portions 252A, 252B. Furthermore, a spacer structure 263A may be provided so as to comply with the overall process and device requirements. The drain and source regions 251 may be formed on the basis of any appropriate manufacturing strategy, for instance by performing implantation processes so as to incorporate drain and source dopant species, possibly counter-doping species and the like and performing appropriate anneal processes so as to activate the dopants and re-crystallize implantation-induced damage. In other cases, a certain amount of the drain and source dopant species may be incorporated upon forming the material 252, as already discussed above. It should be appreciated that, in the embodiments shown in FIGS. 2c and 2d, the portion 252B comprising the carbon and/or nitrogen species may be provided as a substantially flush configuration, while, in other cases, a certain degree of over-fill may be used, if considered appropriate. In this case, corresponding implantation parameters may be readily adapted to the corresponding transistor configuration.

FIG. 2e schematically illustrates the device 200 in a further advanced manufacturing stage according to some illustrative embodiments in which, based on the device 200 as shown in FIG. 2d, a silicidation process may be applied. To this end, an appropriate refractory metal layer may be deposited, for instance by depositing a platinum-containing nickel layer and performing an anneal process with temperatures in the range of approximately 300-350° C. in order to form a metal silicide 253 on any exposed semiconductor surface areas, such as the portion 252B (FIG. 2d). In some illustrative embodiments, the process parameters may be readily determined such that a metal silicide 253 may have substantially the same thickness as the material portion 252B (FIG. 2d), which may be accomplished by controlling the deposition process and the silicidation process, as also discussed above. After the metal/semiconductor diffusion, any non-reacted metal material may be removed by selective etch techniques, possibly followed by additional heat treatments, if considered appropriate. Hence, a metal silicide 262B may be formed in the electrode material 262 when comprising a significant amount of silicon material, while the metal silicide 253 may be provided as a substantially uniform material layer wherein additional agglomeration in any subsequent process stages may be efficiently avoided due to the presence of the nitrogen and/or carbon species, as discussed above. Consequently, the further processing may be continued by forming an appropriate interlayer dielectric material, possibly by using highly stressed material and applying any subsequent treatments, such as a UV treatment and the like, in order to appropriately adjust the desired stress levels.

That is, upon forming the metal silicide 253 which may include a certain amount of nitrogen and/or carbon, while the portion 252A may substantially comprise none or at least a significantly reduced concentration of these species, the further processing may be continued with significantly less constraints in terms of a thermal budget to be applied, while, on the other hand, the active region 202A and the portion 252A are substantially not influenced by nitrogen and/or carbon, while also in any other device areas, such as substrate diodes, fin diodes, N-channel transistors and the like, also any influence of the agglomeration-hindering mechanism provided on the basis of the material 252B (FIG. 2d) may be avoided.

FIG. 2f schematically illustrates the device 200 in a further advanced manufacturing stage. As shown, a contact level may be provided, at least partially, and may comprise dielectric materials 221, 222, for instance in the form of silicon nitride and silicon dioxide, respectively, wherein, for instance, the layer 221 may be provided with a high internal stress level. In this case, undue nickel agglomeration may be avoided within the material 252, as discussed above. In this case, any contact openings 223A extending to the drain and source regions 251 may be formed on the basis of a substantially continuous metal silicide material, thereby providing the desired etch stop capabilities. In this case, undue etching into the active region 202A may be avoided, while also superior contact conductivity may be achieved, as is also discussed above.

In other illustrative embodiments, as shown in FIG. 2f, the portion 252B may be present in the material 252 since a metal silicide may still have to be formed through the contact openings 223A, thereby providing the corresponding metal silicide in a highly locally restricted manner, as may be required in some sophisticated process strategies. Also in this case, irrespective of the lateral size of the contact openings 223A, further processing may be continued by performing a silicidation process in order to form a continuous metal silicide, as described above, while, in any subsequent process steps, superior flexibility may be achieved with respect to any additional heat treatments that may be necessary during the further processing. On the other hand, in other contact openings 223B, for instance connecting to a substrate diode 270, a metal silicide may be formed on the basis of appropriate process conditions wherein, due to the absence of a germanium material, a metal silicide may be formed without requiring incorporation of a nitrogen and/or carbon species. In still other illustrative embodiments, as shown in FIG. 2f, material 252 may be provided without a previously incorporated nitrogen and/or carbon species, which may then be selectively introduced through the contact openings 223A, however, without unduly affecting other device areas. To this end, an appropriate sacrificial fill material 206, such as a resist material, a polymer material and the like, may be provided and may be selectively removed, at least to a certain extent, from the contact openings 223A, which may be accomplished on the basis of non-critical lithography techniques. Thereafter, an implantation process may be applied so as to incorporate the carbon and/or nitrogen species through the openings 223A, while undue incorporation of these species through the contact opening 223B may be blocked by the sacrificial fill material 206. Prior to or after the implantation process, a metal silicide may be formed, depending on the overall process strategy, wherein a species provided by the implantation process may thus efficiently block the nickel agglomeration, as discussed above, during the further processing of the device 200. Hence, upon further continuing with forming contact elements in the openings 223A, 223B by depositing any appropriate conductive material, a substantially uniform metal silicide layer may thus provide the desired low contact resistivity, while additionally any further high temperature processes may be applied without inducing undue nickel agglomeration.

In other sophisticated approaches, such additional heat treatments may have to be applied upon performing a replacement gate approach after forming contact elements in the openings 223A, 223B. To this end, at least the material 262 may be removed and any other appropriate metal-containing materials may be deposited, possibly in combination with a high-k dielectric material, so as to form the gate dielectric material 261 so as to exhibit the desired characteristics. Typically, work function metal species may have to be incorporated and may be diffused on the basis of elevated temperatures, wherein the previously incorporated argon and/or nitrogen species may thus provide the required thermal budget.

As a result, the present disclosure provides semiconductor devices and manufacturing techniques in which undue agglomeration of metal species, such as nickel, in a metal/semiconductor compound may be strongly suppressed by incorporating a nitrogen and/or carbon species in a highly controllable manner. To this end, in some illustrative embodiments, the epitaxial growth process may be appropriately modified so as to incorporate the species in a specified portion of the strain-inducing semiconductor alloy without requiring any additional masking steps and without affecting any other device areas. In other illustrative embodiments, the nitrogen and/or carbon species may be incorporated on the basis of an implantation process performed in the presence of contact openings, wherein a sacrificial fill material may avoid incorporation of the species into sensitive device areas, such as diode structures and the like, wherein the effect of the implantation process on any other dielectric surface areas may be highly uniform, thereby not contributing to additional pronounced surface topography.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
performing an epitaxial growth process so as to form, in a first phase of said epitaxial growth process, a crystalline silicon/germanium containing material on a semiconductor material of an active region of a P-channel transistor and so as to form, in a subsequent second phase of said epitaxial growth process, at least one of a carbon-doped and a nitrogen-doped silicon/germanium-containing material;
forming drain and source regions in said active regions; and
forming a metal/semiconductor compound in said at least one of a carbon-doped and a nitrogen-doped silicon/germanium-containing material.

2. The method of claim 1, wherein a carbon-doped silicon/germanium-containing material is formed in said second phase.

3. The method of claim 1, wherein said at least one of a carbon-doped and a nitrogen-doped silicon/germanium-containing material is formed with a thickness of 4-25 nm.

4. The method of claim 1, wherein forming said metal/semiconductor compound comprises forming a platinum and nickel containing compound.

5. The method of claim 1, wherein forming said at least one of a carbon-doped and a nitrogen-doped silicon/germanium-containing material comprises incorporating said at least one of carbon and nitrogen with a concentration of 1 atomic percent or less.

6. The method of claim 1, further comprising forming a gate electrode structure above said active region prior to performing said epitaxial growth process.

7. The method of claim 6, wherein forming said gate electrode structure comprises providing a high-k dielectric material in a gate insulation layer of said gate electrode structure.

8. The method of claim 1, further comprising forming an interlayer dielectric material above said active region after forming said metal/semiconductor compound.

9. The method of claim 1, further comprising forming an interlayer dielectric material above said active region, forming a contact opening in said interlayer dielectric material and forming said metal/semiconductor compound through said contact opening.

10. A method of forming a semiconductor device, the method comprising:
forming cavities in an active region of a P-channel transistor laterally adjacent to a gate electrode structure of said transistor;
forming a strain-inducing semiconductor alloy in said cavities;
providing at least one of a carbon species and a nitrogen species in said strain-inducing semiconductor alloy so as to have a highest concentration at and near a surface thereof and so as to have a lowest concentration at an interface formed between said strain-inducing semiconductor alloy and a remaining portion of said active region;
forming drain and source regions at least in said strain-inducing semiconductor alloy; and
forming a metal silicide in said strain-inducing semiconductor alloy.

11. The method of claim 10, wherein providing said at least one of a carbon species and a nitrogen species in said strain-inducing semiconductor layer comprises incorporating said at least one of a carbon species and a nitrogen species into a portion of said strain-inducing semiconductor alloy when forming said strain-inducing semiconductor alloy.

12. The method of claim 11, wherein forming said strain-inducing semiconductor alloy comprises performing an epitaxial growth process and incorporating said at least one of a carbon species and a nitrogen species during a final phase of said epitaxial growth process.

13. The method of claim 11, wherein said portion extends from a surface of said strain-inducing semiconductor alloy to a depth of 25 nm or less.

14. The method of claim 10, wherein providing said at least one of a carbon species and a nitrogen species in said strain-inducing semiconductor layer comprises forming at least a portion of an interlayer dielectric material above said active region, forming a contact opening in said at least a portion of said interlayer dielectric material and introducing said at least one of a carbon species and a nitrogen species through said contact opening prior to forming said metal silicide.

15. The method of claim 14, wherein introducing said at least one of a carbon species and a nitrogen species through said contact opening comprises forming a sacrificial fill material in said contact opening and a second contact opening, removing at least a portion of said sacrificial fill material selectively from said contact opening and performing an implantation process.

16. The method of claim 10, wherein providing said at least one of a carbon species and a nitrogen species in said strain-inducing semiconductor layer comprises providing said carbon species with a maximum concentration of 1 atomic percent or less.

17. The method of claim 10, further comprising forming said gate electrode structure so as to comprise a high-k dielectric material in a gate insulation layer prior to forming said cavities.

18. A semiconductor device, comprising:
an active region formed above a substrate;
a gate electrode structure formed on said active region;
drain and source regions formed in said active region;
a strain-inducing germanium-containing semiconductor material formed at least partially in said drain and source regions; and
a metal/semiconductor compound formed in said germanium-containing semiconductor material, said metal/semiconductor compound comprising at least one of carbon and nitrogen with a concentration that is greater than a concentration of said at least one of carbon and nitrogen in a remaining portion of said active region.

19. The semiconductor device of claim 18, wherein a thickness of said metal/semiconductor compound is 25 nm or less.

20. The semiconductor device of claim 19, wherein said gate electrode structure has a gate length of 50 nm or less and comprises a high-k dielectric material.
